(19) United States
(12) Patent Application Publication
(10) Pub. No.: US 2022/0271120 A1
(43) Pub. Date: Aug. 25, 2022

(54) SUPERJUNCTION SEMICONDUCTOR DEVICE

(71) Applicant: DB HiTek Co., Ltd., Bucheon-si (KR)

(72) Inventors: Young Kwon KIM, Haenam-gun (KR); Jae Hyun KIM, Seoul (KR); Ji Eun LEE, Bucheon-si (KR); Jong Min KIM, Seoul (KR)

(21) Appl. No.: 17/574,211

(22) Filed: Jan. 12, 2022

(30) Foreign Application Priority Data
Feb. 25, 2021 (KR) 10-2021-0025739

(51) Int. Cl. H01L 29/06; H01L 29/78

(52) U.S. Cl. CPC H01L 29/0634; H01L 29/7811

(57) ABSTRACT

A superjunction semiconductor device is disclosed. The superjunction semiconductor device includes a gate pad and first conductive type pillars in a ring region adjacent to the gate pad and crossing a gate pad region to a cell region, thereby securing a sufficient depletion region within a relatively short time and directing or guiding excess carriers below the gate pad and in the adjacent ring region toward a source end through or along the pillars during reverse recovery (RR).

### CROSS REFERENCE TO RELATED APPLICATION

The present application claims priority to Korean Patent Application No. 10-2021-0025739, filed Feb. 25, 2021, the entire contents of which are incorporated herein for all purposes by this reference.

### BACKGROUND OF THE INVENTION

### Field of the Invention

The present disclosure relates to a superjunction semiconductor device and, more particularly, to a superjunction semiconductor device configured to secure a sufficient depletion region within a relatively short time by arraying a gate pad to allow all first conductive type pillars provided through a portion of a ring region, the portion being adjacent to the gate pad, to cross a cell region, thereby allowing excess carrier accumulated below the gate pad and the ring region in a reverse recovery (hereinbelow, which is referred to as ‘RR’) to be easily moved toward a source end through the pillars.

### Description of the Related Art

In general, high voltage semiconductor devices such as a MOS field effect transistor (MOSFET) for power and an insulated gate bipolar transistor (IGBT) have a source and a drain respectively provided on an upper surface and a lower surface of a drift region thereof. The high voltage semiconductor device has a gate insulation film on the upper surface of a portion of the drift region adjacent to the source, and a gate electrode on the gate insulator film. The drift region provides, for a drift current flowing from the drain to the source, not only a conductivity path when the high voltage semiconductor device is on, but also a depletion region that is vertically extended by a reverse bias voltage applied when the high voltage semiconductor device is off.

A breakdown voltage of the high voltage semiconductor device is determined by the characteristic of the depletion region in the drift region as described above. In the high voltage semiconductor device, in order to minimize conduction loss occurring in the on state and secure a fast switching speed, research to reduce the turn-on resistance of the drift region providing the conductive path has been carried out.

In general, as a known method, the turn-on resistance of the drift region may be reduced by increasing the dopant density in the drift region. However, when the dopant density in the drift region is increased, there is a problem in that the breakdown voltage decreases as the space charge in the drift region increases.

In order to solve the above problem, a high voltage semiconductor device having a superjunction structure, which includes a new type of junction structure such that the turn-on resistance can be reduced and a high breakdown voltage can be secured, has been developed.

FIG. 1 is a plan view showing a conventional superjunction semiconductor device. FIG. 2 is an enlarged partial view of the superjunction semiconductor device of FIG. 1.

Referring to FIGS. 1 and 2, the conventional superjunction semiconductor device includes a second conductive type epitaxial layer (e.g., an “epi-layer”) 910 on a substrate and a plurality of first conductive type pillars 930 in the epi-layer 910, spaced apart from each other in a first direction (e.g., along the x-axis). Furthermore, in a cell region C, a source electrode (not shown) is on the epi-layer 910. In a gate pad region G, a gate pad may be on the epi-layer 910. The pillars 930 that are exclusively in a ring region R are referred to as first pillars 931, and the pillars 930 in both the ring region R and the cell region C are referred to as second pillars 933.

The gate pad region G is in the ring region R, at an end or on one side in the first direction, and at about a center in a second direction (y-axis). Therefore, the gate pad region G may be at a location adjacent to at least one of the first pillars 931. Some of the second pillars 933 cross through the location (i.e., the gate pad region G).

In the above structure, referring to FIG. 2, the first pillars 931 exclusively in the ring region R do not cross below the gate pad (not shown) and may extend in a second direction, parallel to the gate pad. A hole H in the epi-layer 910 as a charge (or excess) carrier in the ring region R should cross below the gate pad and be discharged through a source electrode (not shown) in the core region during reverse recovery (RR), but the hole H may instead flow to a corner (e.g., at an end of a source) 951 adjacent to the ring region R, which may cause current crowding. For example, a plurality of holes H in the ring region R move toward the corner 951 adjacent to the ring region R to cause congestion (e.g., charge congestion), thereby decreasing the speed at which the holes are discharged. Therefore, the width of the depletion region below the gate pad during RR is reduced, and a corresponding electric field is more highly concentrated in a narrow region of the device, potentially causing a thermal runaway problem.

In order to solve the above problem, the inventors of the present disclosure have created a superjunction semiconductor device with an improved structure and a smaller source.

### DOCUMENTS OF RELATED ART

(Patent Document 1) Korean Patent Application Publication No. 10-2005-0052597 (‘Superjunction semiconductor device’)

### SUMMARY OF THE INVENTION

Accordingly, the present disclosure has been made keeping in mind the above problems occurring in the related art, and the present disclosure is intended to provide a superjunction semiconductor device, the superjunction semiconductor device being configured to secure a sufficient depletion region (e.g., in the epitaxial layer in a gate pad region of the device) within a relatively short time, in which first conductive type pillars in a portion of a ring region adjacent to the gate pad region and crossing to a cell region to move or allow charge carriers and/or excess carriers in the gate pad region and the adjacent ring region to move toward a source end (e.g., in the cell region) through or along the pillars during reverse recovery (RR).

Another objective of the present disclosure is intended to provide a superjunction semiconductor device configured to solve a problem of charge and/or excess carriers accumulating during RR by changing an arrangement, orientation, configuration and/or location of a gate pad or gate pad region, without additional configurational or design changes.

In order to achieve the above objective, according to one aspect of the present disclosure, there is provided a superjunction semiconductor device including a substrate; a drain electrode under the substrate; an epitaxial layer on the substrate; a plurality of pillars in the epitaxial layer, spaced apart from each other in a first direction; a gate on the epitaxial layer in a cell region and a gate pad region; a source electrode on the gate and the epitaxial layer in the cell region; and a gate electrode on the gate and the epitaxial layer in the gate pad region, wherein the plurality of pillars may include first pillars extending across the cell region in a second direction and having opposite ends in a ring region; and second pillars completely in the ring region and extending in the second direction.

The gate pad region may be adjacent to a source end of the source electrode (e.g., in the cell region), but may not be adjacent to (e.g., is separated or spaced apart from) the second pillars. For example, the gate pad region may be spaced from the second pillars by a part or portion of the cell region containing a subset of two or more of the first pillars.

The gate pad region may be in or adjacent to the ring region at a center portion of the ring region in the second direction.

The gate pad region may be in or adjacent to the ring region, and the first pillars may be perpendicular to an interface between the ring region and the gate pad region.

The gate pad region may exclude the second pillars.

In order to achieve the above objective, according to another aspect of the present disclosure, there is provided a superjunction semiconductor device, the superjunction semiconductor device including: a substrate; a drain electrode under the substrate; a plurality of pillars spaced apart from each other in an epitaxial layer in a first direction, the pillars including first pillars crossing a cell region in a second direction and having opposite ends in a ring region, and second pillars completely in the ring region and extending in the second direction; a gate on the epitaxial layer in the cell region and a gate pad region; a source electrode on the gate and the epitaxial layer in the cell region; and a gate electrode on the gate and the epitaxial layer in the gate pad region, wherein the gate pad region may not be adjacent to (e.g., is separated or spaced apart from) the second pillars, as described herein.

The superjunction semiconductor device may further include body regions on the first pillars in the epitaxial layer; and sources in the body regions.

The superjunction semiconductor device may further include a gate pad (e.g., in the gate pad region) configured to allow a charge carrier or excess carrier (e.g., holes) in the ring region to cross below the gate pad, through or along the first pillars, toward a source end (e.g., in the core region) during reverse recovery.

The gate pad region may exclude the second pillars.

The superjunction semiconductor device may further include a body contacts in the body region, which may be in contact with the source or a location adjacent to the source.

In order to achieve the above objective, according to another aspect of the present disclosure, there is provided a superjunction semiconductor device, the superjunction semiconductor device including: a substrate; a drain electrode under the substrate; an epitaxial layer comprising a second conductive type dopant on the substrate; a plurality of pillars spaced apart from each other in the epitaxial layer in a first direction, and including first pillars crossing a cell region in a second direction, comprising a first conductive type dopant and opposite ends in a ring region, and second pillars completely in the ring region, comprising the first conductive type dopant; first conductive type body regions on the first pillars in the epitaxial layer; second conductive type sources in the body regions; a gate on the epitaxial layer in the cell region and a gate pad region; a source electrode on the gate and the epitaxial layer in the cell region; and a gate electrode in the gate pad region, adjacent to a source end of the source electrode (e.g., in the cell region) and on the gate and the epitaxial layer, wherein the first pillars cross below a gate pad (e.g., in the gate pad region), and the gate pad region does not include the second pillars.

The gate pad region may be adjacent to or in the ring region, and the first pillars may be perpendicular to an interface between the ring region and the gate pad region.

The gate pad may have a shape (or an edge with a shape) complementary to that of the source end of the source electrode, and substantially, may have a rectangular or substantially rectangular shape.

The present disclosure has the following effects by the above described configuration.

The superjunction semiconductor device of the present disclosure is configured to array a gate pad to allow all first conductive type pillars in a portion of a ring region, the portion being adjacent to excess carrier the gate pad, to cross a cell region, thereby allowing excess carrier accumulated at the gate pad and the ring region in the RR to be easily moved toward a source end through the pillars. Therefore, a sufficient depletion region can be secured within a relatively short time.

The superjunction semiconductor device of the present disclosure is configured to change an arrangement, orientation, configuration and/or location of a gate pad and/or gate pad region without additional configurational or design changes. Therefore, the problem caused by charge and/or excess carriers during RR can be solved.

Even if effects are not explicitly mentioned in the specification, the effects described in the following specification expected by the technical characteristics of the present disclosure and potential effects thereof are treated as if the effects are described in the specification of the present disclosure.

### BRIEF DESCRIPTION OF THE DRAWINGS

The above and other objectives, features, and other advantages of the present disclosure will be more clearly understood from the subsequent detailed description when taken in conjunction with the accompanying drawings, in which:

FIG. 1 is a plan view showing a conventional superjunction semiconductor device;

FIG. 2 is an enlarged partial view of the superjunction semiconductor device of FIG. 1;

FIG. 3 is a plan view showing a superjunction semiconductor device according to an embodiment of the present disclosure;

FIG. 4 is a cross-sectional view taken along line A-A′ in the superjunction semiconductor device of FIG. 3; and

FIG. 5 is an enlarged partial view of the superjunction semiconductor device of FIG. 3.

### DETAILED DESCRIPTION OF THE INVENTION

Hereinbelow, various embodiments of the present disclosure will be described in detail with reference to the accompanying drawings. It should be understood that the embodiments of the present invention may be changed to a variety of other embodiments, and the scope and spirit of the present invention are not limited to the embodiments described hereinbelow. The embodiments of the present invention described hereinbelow are provided to allow those skilled in the art to more clearly comprehend the present invention.

Hereinbelow, if it is described that a first component (or layer) is on a second component (or layer), it should be understood that the first component may be directly on the second component, or one or more components or layers may be between the components. Furthermore, if it is described that the first component is directly on the second component, no additional components are between the first and second components. A location ‘on’, ‘upper’, ‘lower’, ‘above’, and ‘below’ or ‘beside’ the first component may describe a relative location relationship.

Terms such as ‘a first ˜’, ‘a second ˜’, and ‘a third ˜’ are used only for the purpose for describing various elements such as various components, regions, and/or parts, and the various elements are not limited to the terms.

It should also be noted that, in cases where certain embodiments are otherwise practicable, certain process sequences may be performed differently from those described below. For example, two processes described in succession may be performed substantially simultaneously or in a reverse order.

The term MOS (metal-oxide semiconductor) used herein is a general term, and ‘M’ is not limited to metal, but may encompass any of various types of conductors. In addition, ‘S’ may be a substrate or a semiconductor structure, and ‘0’ may be an oxide such as silicon dioxide, but is not limited to oxides, and may include various types of organic or inorganic insulating materials.

In addition, a conductivity type or a doped region of the components may be defined as ‘P-type’ or ‘N-type’ depending on the main carrier properties, but such labels are only for convenience of the description, and the technical idea of the present disclosure is not limited to the embodiment. For example, ‘P-type’ or ‘N-type’ may be replaced herein with the more general terms ‘first conductive type’ or ‘second conductive type’. The first conductive type may refer to P-type, and the second conductive type may refer to N-type, but the present disclosure is not limited thereto.

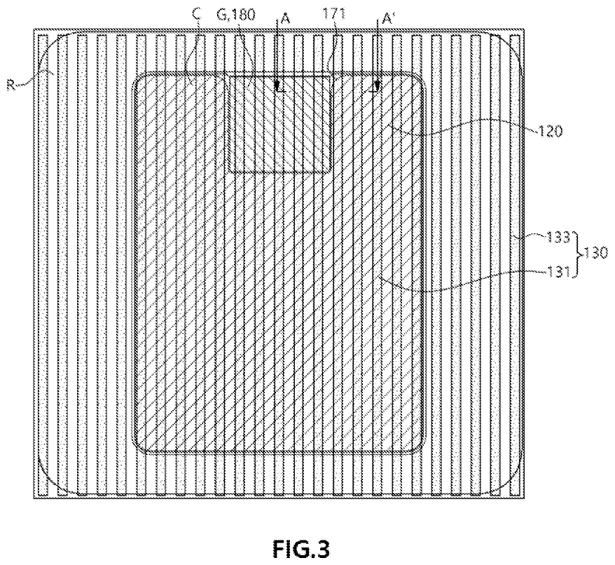

Referring to FIG. 3, according to an embodiment of the present disclosure, a cell region C, as an activation region, is in a center portion of a superjunction semiconductor device 1, and a ring region R, as a termination region, encloses the cell region C. The cell region C is inside the ring region R. A region G that includes a gate pad is between the cell region C and the ring region R. In other words, the gate pad region G is in a location other than the cell region C and the ring region R. As will be described in detail below, the gate pad region G does not include a source. Furthermore, a transition region may be between the cell region C and the ring region R, but the description thereof will be omitted below for convenience.

Furthermore, in the specification, based on the accompanying drawings, the x-axis direction may be referred to as ‘a first direction’, and the y-axis direction may be referred to as ‘a second direction’.

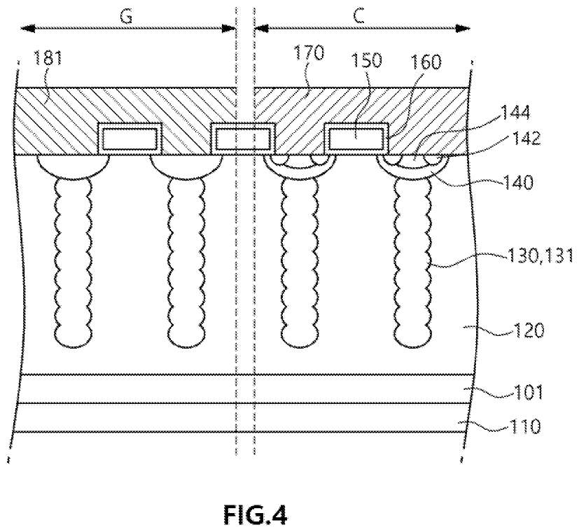

FIG. 3 is a plan view showing a superjunction semiconductor device according to an embodiment of the present disclosure. FIG. 4 is a cross-sectional view taken along line A-A′ in the superjunction semiconductor device of FIG. 3.

Hereinbelow, the superjunction semiconductor device according to the present disclosure will be described in detail with reference to the accompanying drawings.

Referring to FIGS. 3 and 4, the present disclosure relates to the superjunction semiconductor device and, more particularly, to the superjunction semiconductor device including a gate pad and first conductive type pillars in a ring region R adjacent to the gate pad and crossing the cell region C, configured to direct or guide excess carriers below the gate pad and in the ring region toward a source end through the pillars during reverse recovery (RR), so that a depletion region may be sufficiently secured within a relatively short time.

First, the superjunction semiconductor device includes a substrate 101. The substrate 101 may be or comprise a silicon substrate, a germanium substrate, or bulk wafer with an epi-layer thereon. Furthermore, the substrate 101 may be or comprise, for example, a heavily doped second conductive type substrate. In addition, a drain electrode 110 may be below the substrate 101 in both the cell region C and the ring region R. The drain electrode 110 may comprise, for example, gold, silver, nickel, copper or an alloy thereof, but the scope of the present disclosure is not limited thereto.

Furthermore, an epitaxial layer 120 is in both the cell region C and the ring region R on the substrate 101. The epitaxial layer 120 comprises, for example, silicon lightly doped h a second conductive type dopant, and may be formed by epitaxial growth. A plurality of pillars 130 comprise first conductive type regions in the epitaxial layer 120 that are more heavily doped than the epitaxial layer 120. The pillars 130 may extend vertically into the epitaxial layer 120 toward the substrate 101 by a predetermined distance from the uppermost surface of the epitaxial layer 120.

As described above, a surface of each of the pillars 130 in contact with the epitaxial layer 120 may be flat or curved, and the curved surfaces may be complementary to each other, but the present disclosure is not limited thereto. Furthermore, each individual pillar 130 is spaced apart from another (e.g., an adjacent) individual pillar 130 in a first direction and may extend (e.g., toward the substrate 101) in a second direction. The second direction may be orthogonal to the first direction. Therefore, the pillars 130 may alternate with the epitaxial layer 120 in the first direction in the cell region C, the ring region R, and the gate pad region G.

Referring to FIG. 3, the pillars 130 in the cell region C respectively have opposite ends in opposite portions of the ring region R in the second direction, and the pillars 130 that cross the cell region C are referred to as first pillars 131. Furthermore, the pillars 130 that are completely or exclusively in the ring region R are referred to as second pillars 131. The second pillars 131 may not cross or be in the cell region C. The number of the first pillars 131 and the number of the second pillars 131 are not limited, but they are generally linear and parallel to each other, and may be in rows or columns.

Referring to FIGS. 3 and 4, a first conductive type body region 140 is on each of the pillars 130 in the cell region C and the gate pad region G. The device may include a plurality of first conductive type body regions 140 respectively connected to the upper surface of a corresponding one of the first pillars 131, in an upper portion of the epitaxial layer 120. The body region 140 may extend in the first direction by a predetermined distance. Furthermore, a source 142, as a region heavily doped with a second conductive type dopant, is in the body region 140 in the cell region C. A body contact 144 may be at a location adjacent to the source 142 or in contact with the source 142. The source 142 may include two source regions in left and right sides of the body region 140 in the first direction, but the present disclosure is not limited thereto. For example, the body region 140 may contain a single source 142. The source 142 and the body contact 144 are not in the body region 140 in the gate pad region G.

Furthermore, a gate 150 is on the epitaxial layer 120 in both the cell region C and the gate pad region G. A channel region (e.g., in the epitaxial layer 120) may be turned on and off by a voltage applied to the gate 150. The gate 150 may comprise, for example, a conductive polysilicon, a metal, a conductive metal nitride, a refractory metal silicide, or a combination thereof. Furthermore, gate insulation 160, comprising a gate oxide film under the gate 150, a gate sidewall layer, and an interlayer insulating film, may enclose an outer surface of the gate 150. the gate insulation 160 may comprise a silicon dioxide film, a high-k dielectric film, silicon nitride, or a combination thereof.

Furthermore, a source electrode 170 may be on both the gate 150 and the epitaxial layer 120 in the cell region C. The source electrode 170 is in contact with the body region 140, and thus, in contact with the source 142 and the body contact 144. The source electrode 170 may comprise, for example, gold, silver, nickel, copper or an alloy thereof, but the scope of the present disclosure is not limited thereto. The source electrode 170 is not in the gate pad region G and the ring region R, and is preferably only in the cell region C. Therefore, a source end 171 may be at a location in the cell region C adjacent to a boundary or interface with the gate pad region G.

The gate pad 180 may be in the gate pad region G. For example, one portion of an otherwise substantially rectangular (e.g., rectangular with rounded corners) source electrode 170 includes a cutout from an outer edge toward the center thereof. The gate electrode 181 or the gate pad region G may be in the cutout space, but the present disclosure is not limited thereto. Therefore, the source end 171 may be at a location adjacent to an edge of the gate pad 180. The gate pad 180 may have, for example, a rectangular or substantially rectangular plan shape, but the present disclosure is not limited thereto.

The gate pad region G may have the gate electrode 180 on the gate 150 and the epitaxial layer 120. The gate electrode 180 is to be in contact with the body region 140 in the gate pad region G, and may comprise, for example, gold, silver, nickel, copper or an alloy thereof, but the scope of the present disclosure is not limited thereto. The gate electrode 180 may be in electrical contact with a plurality of the gates 150 to supply a common gate voltage to the plurality of gates 150. Furthermore, the gate electrode 180 and the source electrode 170 may be separated from each other directly or indirectly by an insulator film (not shown).

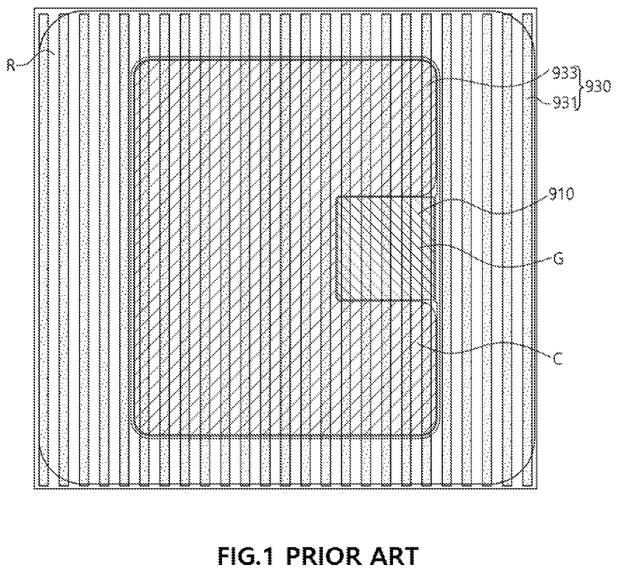

A significant difference between the conventional superjunction semiconductor device and the superjunction semiconductor device of the present disclosure may be in the orientation of the core, gate pad, and ring regions C, G and R relative to the pillars 130. In FIG. 1, the conventional superjunction semiconductor device includes three types of pillars 130: those that are completely in the ring region R, those having a relatively large central portion in the core region C and end portions in the ring region R, and those having a relatively small central portion in the gate pad region G, end portions in the ring region R, and intervening portions in the core region C. The intervening portions of the third type of pillars 130 are separated by the relatively small central portion in the gate pad region G. As shown in FIG. 3, the superjunction semiconductor device of the present disclosure also includes three types of pillars 130. Two of the types (those that are completely in the ring region R and those having a relatively large central portion in the core region C and end portions in the ring region R) are the same or substantially the same as in the conventional superjunction semiconductor device. However, the third type of pillar 130 in the superjunction semiconductor device of the present disclosure has end portions in the ring region R, a relatively small portion at one side in the gate pad region G, and a relatively large portion in the center and at the other side in the core region C. In other words, at one end of the relatively small portion in the gate pad region G, there is no intervening portion between the relatively small portion and the end portion in the ring region R. This orientation of the core, gate pad, and ring regions C, G and R relative to the pillars may enable those pillars that have a portion in the ring region, adjacent to the gate pad and crossing the gate pad region to a cell region, to secure a sufficient depletion region and/or to direct or guide excess carriers below the gate pad and in the adjacent ring region through or along the pillars toward a source end in the core region C during reverse recovery (RR).

Hereinbelow, the structure of the conventional superjunction semiconductor device, a problem thereof, and the superjunction semiconductor device according to the present disclosure for solving the problem will be described in detail.

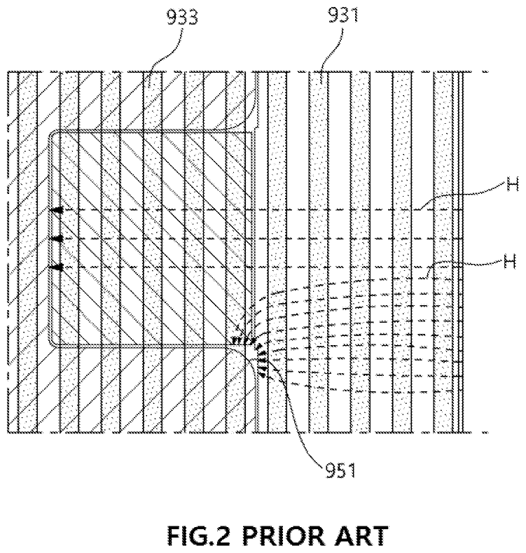

Referring to FIGS. 1 and 2, the conventional superjunction semiconductor device includes the second conductive type epi-layer 910 on the substrate and a plurality of first conductive type pillars 930 in the epi-layer 910, spaced apart from each other in a first direction. Furthermore, in the cell region C, the source electrode (not shown) is on the epi-layer 910. In the gate pad region G, a gate pad (not shown) may be on the epi-layer 910. Some of the pillars 930 that are completely in the ring region R are referred to as first pillars 931, and other pillars 930 crossing both the ring region R and the cell region C are referred to as second pillars 933.

The gate pad region G may be in or adjacent to the ring region R, at an end in the first direction, and at about a center portion in a second direction (wherein the second direction may be orthogonal to the first direction). Therefore, the gate pad region G may be at a location adjacent to one or more of the first pillars 931, and through which some of the second pillars 933 cross.

In this structure, referring to FIG. 2, during RR, the first pillars 931 that are entirely in the ring region R do not cross below the gate pad and are parallel to the gate pad or an edge or sidewall thereof. Holes H, as a charge (or excess) carrier in the epi-layer 910, should cross below the gate pad and be discharged through a source electrode, but the holes H instead are attracted or directed to a corner of a source end 951, which may cause current crowding. For example, the holes H may move toward the source end 951 adjacent to the ring region R to cause a congestion situation, and thus decrease the speed at which the holes are discharged. Therefore, the width of the depletion region below the gate pad during RR is reduced, whereby the resulting electric field is more concentrated in a narrow region, which may cause a thermal runaway problem.

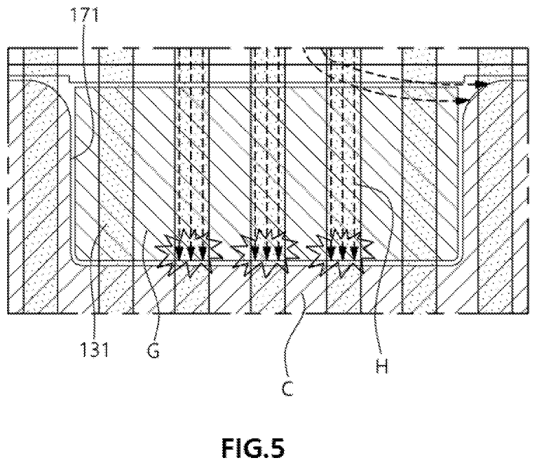

FIG. 5 is an enlarged partial view of the superjunction semiconductor device of FIG. 3.

In order to prevent the above problem, referring to FIGS. 3 and 5, the superjunction semiconductor device according to the present disclosure is configured such that the edge or sidewall of the gate pad 180 or the border of the gate pad region G closest to the ring region R is not parallel with (and may be perpendicular to) the pillars 131 that pass through the ring region R and the immediately adjacent gate pad region G. For example, the gate pad 180 or the gate pad region G may be at or adjacent to a center portion of the ring region R in the second direction. In other words, the gate pad 180 is at a location adjacent to both the cell region C and the ring region R, and the first pillars 131 may be perpendicular to the interface between the ring region R and the gate pad region G. The gate pad 180 may not include any portion of some of the second pillars 131.

With the above structure, the holes H below the gate pad 180 in the gate pad region G, and in the nearby ring region R, can rapidly move toward a source end in the cell region C adjacent thereto, along the first pillars 131 crossing the gate pad 180, so that current crowding can be reduced and a depletion region can be sufficiently secured (e.g., in the epitaxial layer 120 in the gate pad region G) within a relatively short time.

The detailed descriptions disclosed herein are only to illustrate the present disclosure. Furthermore, the foregoing is intended to represent and describe various embodiments of the present disclosure, and the present disclosure may be used in various other combinations, variations, and environments. Changes or modifications are possible within the scope of the concepts of the invention disclosed herein, the scope equivalent to the written disclosure, and/or within the scope of skill or knowledge in the art. The above-described embodiments describe the best state for implementing the technical idea of the present disclosure, and various changes required in specific application fields and uses of the present disclosure are possible. Therefore, the detailed description of the above invention is not intended to limit the present disclosure to the disclosed embodiments.

What is claimed is:

1. A superjunction semiconductor device comprising:
a substrate;
a drain electrode under the substrate;
an epitaxial layer on the substrate;
a plurality of pillars in the epitaxial layer, spaced apart from each other in a first direction;
a gate on the epitaxial layer in a cell region and a gate pad region;
a source electrode on the gate and the epitaxial layer in the cell region; and
a gate electrode on the gate and the epitaxial layer in the gate pad region,
wherein the plurality of pillars comprise:
first pillars extending across the cell region in a second direction and having opposite ends in a ring region; and
second pillars completely in the ring region and extending in the second direction.

2. The superjunction semiconductor device of claim 1, wherein the gate pad region is adjacent to a source end of the source electrode and not adjacent to the second pillars.

3. The superjunction semiconductor device of claim 2, wherein the gate pad region is in or adjacent to the ring region at a center portion of the ring region in the second direction.

4. The superjunction semiconductor device of claim 2, wherein the gate pad region is in or adjacent to the ring region, and the first pillars are perpendicular to an interface between the ring region and the gate pad region.

5. The superjunction semiconductor device of claim 2, wherein the gate pad region excludes the second pillars.

6. The superjunction semiconductor device of claim 1, wherein the gate pad region is spaced from the second pillars by a part or portion of the cell region containing a subset of two or more of the first pillars.

7. The superjunction semiconductor device of claim 2, wherein the source end of the source electrode is in the cell region.

8. A superjunction semiconductor device comprising:
a substrate;
a drain electrode under the substrate;
a plurality of pillars spaced apart from each other in an epitaxial layer in a first direction, the pillars comprising first pillars crossing a cell region in a second direction and having opposite ends in a ring region, and second pillars completely in the ring region and extending in the second direction;
a gate on the epitaxial layer in the cell region and a gate pad region;
a source electrode on the gate and the epitaxial layer in the cell region; and
a gate electrode on the gate and the epitaxial layer in the gate pad region,
wherein the gate pad region is not adjacent to the second pillars.

9. The superjunction semiconductor device of claim 8, further comprising:
body regions on the first pillars in the epitaxial layer; and
one or more sources in each of the body regions.

10. The superjunction semiconductor device of claim 9, further comprising a gate pad configured to allow a charge carrier or excess carrier in the ring region to cross below the gate pad, through or along the first pillars, toward a source end during reverse recovery.

11. The superjunction semiconductor device of claim 10, wherein the gate pad region excludes the second pillars.

12. The superjunction semiconductor device of claim 9, further comprising:
body contacts in contact with or adjacent to the sources in the body regions.

13. The superjunction semiconductor device of claim 8, wherein the first pillars are perpendicular to an interface between the ring region and the gate pad region.

14. The superjunction semiconductor device of claim 10, wherein the gate pad is in the gate pad region, the charge carrier or excess carrier comprises a plurality of holes, and the source end is in the core region.

15. A superjunction semiconductor device comprising:
a substrate;
a drain electrode under the substrate;
an epitaxial layer comprising a second conductive type dopant on the substrate;
a plurality of pillars spaced apart from each other in the epitaxial layer in a first direction, and comprising first pillars crossing a cell region in a second direction, comprising a first conductive type dopant and opposite ends in a ring region, and second pillars completely in the ring region, comprising the first conductive type dopant;
first conductive type body regions on the first pillars in the epitaxial layer;
second conductive type sources in the body regions;
a gate on the epitaxial layer in the cell region and a gate pad region;
a source electrode on the gate and the epitaxial layer in the cell region; and
a gate electrode in the gate pad region, adjacent to a source end of the source electrode and on the gate and the epitaxial layer,
wherein the first pillars cross below a gate pad, and at a location without the second pillars in the ring region.

16. The superjunction semiconductor device of claim 15, wherein the gate pad region is at a location adjacent to the ring region in the ring region and enclosed by the first pillars over entire edges thereof.

17. The superjunction semiconductor device of claim 16, wherein the gate pad region has an edge with a shape complementary to the source end of the source electrode.

18. The superjunction semiconductor device of claim 15, further comprising the gate pad, wherein the gate pad is in the gate pad region.

19. The superjunction semiconductor device of claim 15, wherein the first pillars are perpendicular to an interface between the ring region and the gate pad region.
